(19) United States
(12) Patent Application Publication
(10) Pub. No.: US 2015/0263035 A1
(43) Pub. Date: Sep. 17, 2015

(54) METHOD FOR MANUFACTURING SEMICONDUCTOR MEMORY DEVICE

(71) Applicant: Kabushiki Kaisha Toshiba, Minato-ku (JP)

(72) Inventors: Masaki TSUJI, Yokkaichi (JP); Yoshiaki FUKUZUMI, Yokkaichi (JP)

(73) Assignee: Kabushiki Kaisha Toshiba, Minato-ku (JP)

(21) Appl. No.: 14/632,050

(22) Filed: Feb. 26, 2015

(30) Foreign Application Priority Data
Mar. 14, 2014 (JP) 2014-052667

(51) Int. Cl. H01L 27/115

(52) U.S. Cl. CPC H01L 27/11582

(57) ABSTRACT

According to one embodiment, a method for manufacturing a semiconductor memory device processing the first sidewall films into a plurality of island shape patterns. The method includes processing the base mask using the core material films, the first sidewall films, and the second sidewall films as masks to simultaneously form a plurality of mask slits extending in a first direction and a plurality of mask holes in the base mask. The method includes simultaneously forming a plurality of slits extending in the first direction and a plurality of holes in the stacked body using the base mask as a mask. The method includes forming a memory film and a channel body in the hole, and forming an insulating film in the slit.

### CROSS-REFERENCE TO RELATED APPLICATION

This application is based upon and claims the benefit of priority from Japanese Patent Application No. 2014-052667, filed on Mar. 14, 2014; the entire contents of which are incorporated herein by reference.

### FIELD

Embodiments described herein relate generally to a method for manufacturing a semiconductor memory device.

### BACKGROUND

There has been proposed a memory device having a three-dimensional structure in which memory holes are formed in a stacked body formed by stacking, via insulating layers, a plurality of electrode layers functioning as control gates in memory cells and silicon bodies functioning as channels are provided on the sidewalls of the memory holes via charge storage films.

In such a three-dimensional memory device, in order to improve an integration degree of the memory cells, it is required to increase the number of stacked layers of the electrode layers or reduce the diameter of the memory holes to narrow a pitch of the memory holes. However, there are concerns that time for etching the stacked body increases to cause an increase in costs and an interval between slits for insulating the electrode layers in the same layers and the memory holes is narrowed and a sufficient alignment margin of the slits and the memory holes cannot be secured.

### BRIEF DESCRIPTION OF THE DRAWINGS

FIG. 1 is a schematic perspective view of a memory cell array of an embodiment;

FIG. 2 is a schematic sectional view of a memory string of the embodiment;

FIG. 3 is a schematic sectional view of a memory cell of the embodiment; and

FIGS. 4 to 22 are schematic views showing a method for manufacturing a semiconductor device of the embodiment.

### DETAILED DESCRIPTION

According to one embodiment, a method for manufacturing a semiconductor memory device includes forming a base mask on a stacked body including a plurality of electrode layers stacked via an insulating layer. The method includes forming a plurality of core material films of line patterns on the base mask. The method includes forming a plurality of first sidewall films on the base mask. The first sidewall films are respectively provided on sidewalls of the core material films. The method includes forming a plurality of second sidewall films on the base mask. The second sidewall films are respectively provided on sidewalls of the first sidewall films. The second sidewall films are adjacent to each other being separated by a slit. The method includes processing the first sidewall films into a plurality of island shape patterns. The method includes processing the base mask using the core material films, the first sidewall films, and the second sidewall films as masks to simultaneously form a plurality of mask slits extending in a first direction and a plurality of mask holes in the base mask. The method includes simultaneously forming a plurality of slits extending in the first direction and a plurality of holes in the stacked body using the base mask as a mask. The method includes forming a memory film and a channel body in the hole. And the method includes forming an insulating film in the slit.

An embodiment is described below with reference to the drawings. Note that, in the drawings, the same components are denoted by the same reference numerals and signs.

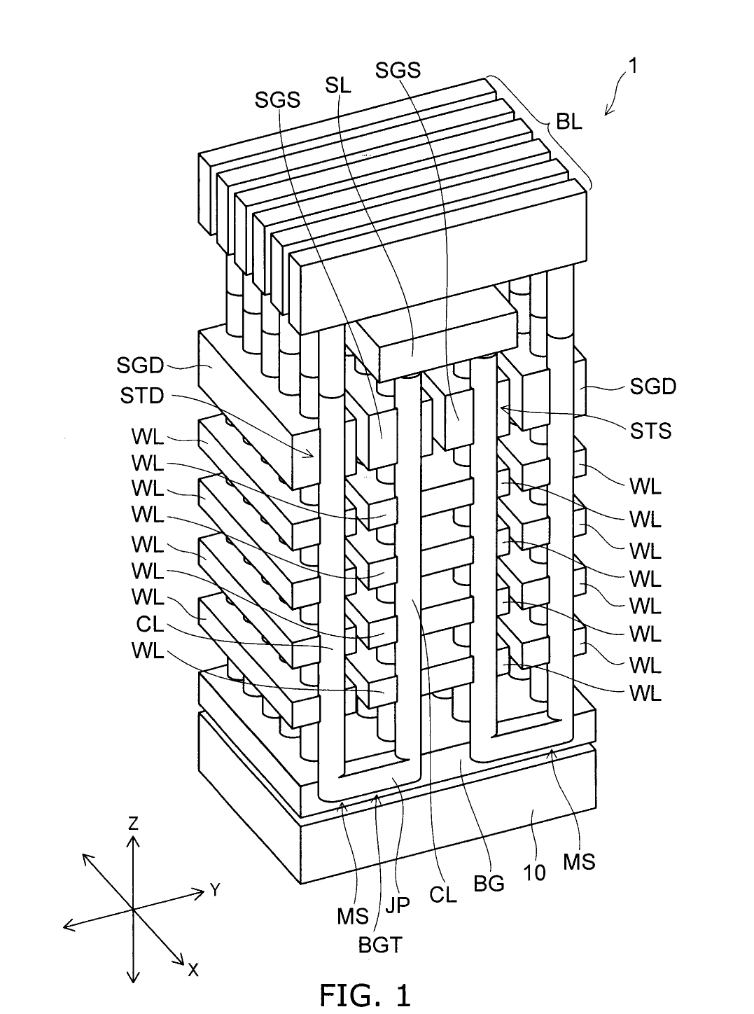

FIG. 1 is a schematic perspective view of a memory cell array 1 of a semiconductor memory device of the embodiment. Note that, in FIG. 1, illustration of insulating layers, isolation films, and the like is omitted to clearly show the figure.

In FIG. 1, two directions parallel to the major surface of a substrate 10 and orthogonal to each other are represented as an X-direction and a Y-direction. A direction orthogonal to both of the X-direction and the Y-direction is represented as a Z-direction (a stacking direction).

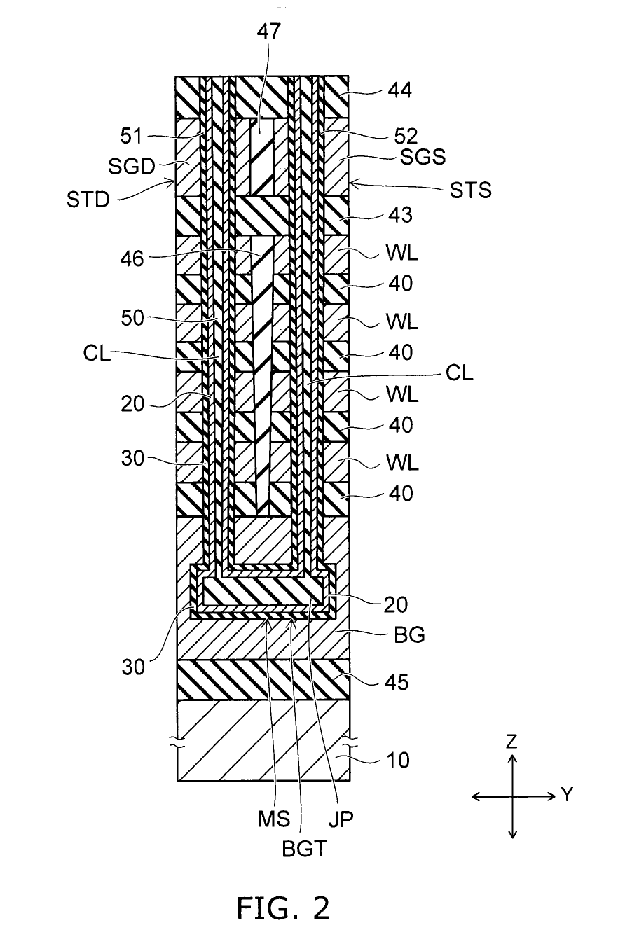

The memory cell array 1 includes a plurality of memory strings MS. FIG. 2 is a schematic sectional view of the memory string MS. FIG. 2 shows a cross section parallel to a Y-Z plane in FIG. 1.

The memory cell array 1 includes a stacked body in which electrode layers WL and insulating layers 40 are alternately stacked layer by layer. The stacked body is provided on a back gate BG functioning as a lower gate layer. Note that the number of the electrode layers WL shown in the figure is an example. The number of the electrode layers WL may be any number.

The back gate BG is provided on the substrate 10 via an insulating layer 45. The back gate BG and the electrode layers WL are layers containing silicon as a main component. Further, the back gate BG and the electrode layers WL contain, for example, boron as impurities for imparting electric conductivity to a silicon layer. The electrode layers WL may contain metal silicide. The insulating layers 40 mainly contain, for example, silicon oxide.

One memory string MS is formed in a U shape including a pair of columnar sections CL extending in the Z-direction and a joining section JP that couples the lower ends of the pair of columnar sections CL. The columnar sections CL are formed in, for example, a columnar or elliptical columnar shape, pierce through the stacked body, and reach the back gate BG.

A drain side selection gate SGD is provided at the upper end portion of one of the pair of columnar sections CL in the U-shaped memory string MS. A source side selection gate SGS is provided at the upper end portion of the other. The drain side selection gate SGD and the source side selection gate SGS are provided on the top electrode layer WL via an interlayer insulating layer 43.

The drain side selection gate SGD and the source side selection gate SGS are layers containing silicon as a main component. Further, the drain side selection gate SGD and the source side selection gate SGS contain, for example, boron as impurities for imparting electric conductivity to a silicon layer.

The drain side selection gate SGD and the source side selection gate SGS functioning as upper selection gates and the back gate BG functioning as a lower selection gate are thicker than one electrode layer WL.

The drain side selection gate SGD and the source side selection gate SGS are separated in the Y-direction by an isolation film 47. The stacked body under the drain side selection gate SGD and the stacked body under the source side selection gate SGS are separated in the Y-direction by an isolation film 46. That is, the stacked body between the pair of columnar sections CL of the memory string MS is separated in the Y-direction by the isolation films 46 and 47.

A source line (e.g., a metal film) SL shown in FIG. 1 is provided on the source side selection gate SGS via an insulating layer 44. A plurality of bit lines (e.g., metal films) BL shown in FIG. 1 are provided on the drain side selection gate SGD and the source line SL via the insulating layer 44. The bit lines BL extend in the Y-direction.

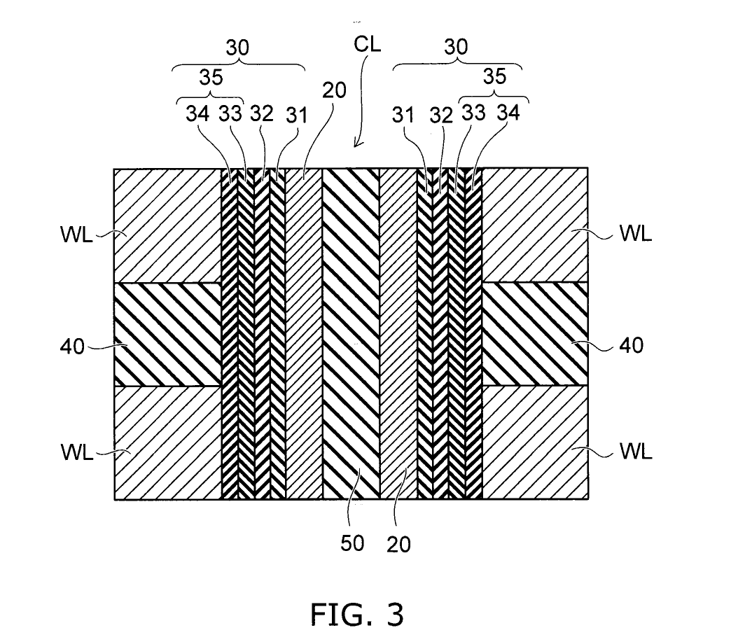

FIG. 3 is an enlarged schematic sectional view of a part of the columnar section CL.

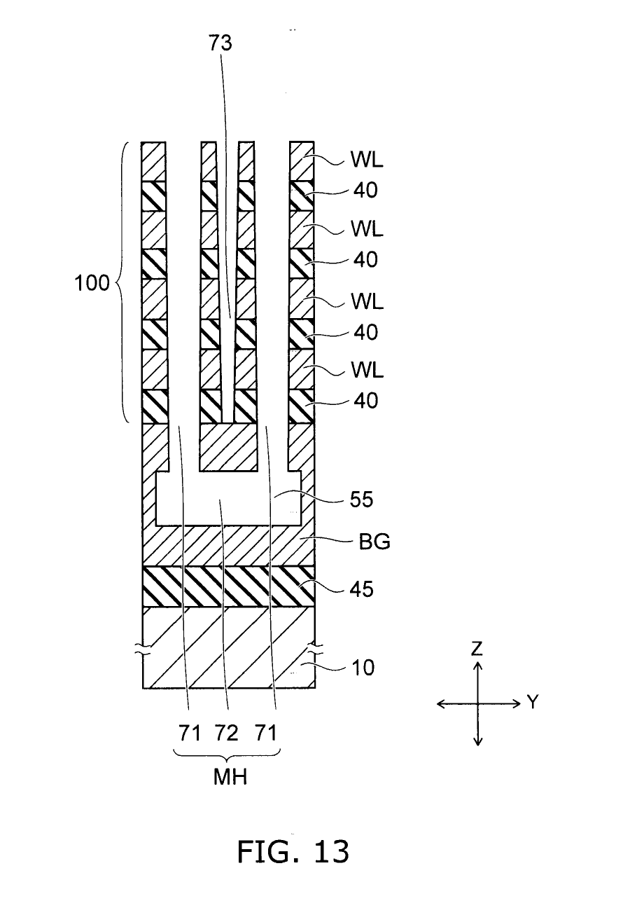

The columnar section CL is formed in a U-shaped memory hole MH shown in FIG. 13 described below. The memory hole MH is formed in the stacked body including the plurality of electrode layers WL, the plurality of insulating layers 40, and the back gate BG.

A channel body 20 functioning as a semiconductor channel is provided in the memory hole MH. The channel body 20 is, for example, a silicon film. The impurity concentration of the channel body 20 is lower than the impurity concentration of the electrode layers WL.

A memory film 30 is provided between the inner wall of the memory hole MH and the channel body 20. The memory film 30 includes a block insulating film 35, a charge storage film 32, and a tunnel insulating film 31.

The block insulating film 35, the charge storage film 32, and the tunnel insulating film 31 are provided in order from the electrode layers WL side between the electrode layers WL and the channel body 20.

The channel body 20 is provided in a cylindrical shape extending in the stacking direction of the stacked body. The memory film 30 is provided in a cylindrical shape while extending in the stacking direction of the stacked body to surround the outer circumferential surface of the channel body 20. The electrode layers WL surround the channel body 20 via the memory film 30. A core insulating film 50 is provided on the inner side of the channel body 20. The core insulating film 50 is, for example, a silicon oxide film.

The block insulating film 35 is in contact with the electrode layers WL. The tunnel insulating film 31 is in contact with the channel body 20. A charge storage film 32 is provided between the block insulating film 35 and the tunnel insulating film 31.

The channel body 20 functions as a channel in the memory cells. The electrode layers WL function as control gates of the memory cells. The charge storage film 32 functions as a data memory layer that accumulates electric charges injected from the channel body 20. That is, the memory cells having structure in which the control gates surround the channel are formed in crossing portions of the channel body 20 and the electrode layers WL.

The semiconductor memory device of the embodiment is a nonvolatile semiconductor memory device in which data can be electrically freely erased and written and stored contents can be retained even if a power supply is turned off.

The memory cells are, for example, memory cells of a charge trap type. The charge storage film 32 includes a large number of trap sites that capture electric charges and is, for example, a silicon nitride film.

The tunnel insulating film 31 functions as a potential barrier when electric charges are injected into the charge storage film 32 from the channel body 20 or when electric charges accumulated in the charge storage film 32 diffuse to the channel body 20. The tunnel insulating film 31 is, for example, a silicon oxide film.

As the tunnel insulating film, a stacked film (an ONO film) having structure in which a silicon nitride film is sandwiched by a pair of silicon oxide films may be used. When the ONO film is used as the tunnel insulating film, an erasing operation can be performed with a low electric field compared with a single layer of a silicon oxide film.

The block insulating film 35 prevents the electric charges accumulated in the charge storage film 32 from diffusing to the electrode layers WL. The block insulating film 35 includes a cap film 34 provided in contact with the electrode layers WL and a block film 33 provided between the cap film 34 and the charge storage film 32.

The block film 33 is, for example, a silicon oxide film. The cap film 34 is a film having a dielectric constant higher than the dielectric constant of silicon oxide and is, for example, a silicon nitride film. By providing the cap film 34 in contact with the electrode layers WL, it is possible to suppress back tunnel electrons injected from the electrode layers WL during erasing. That is, by using a stacked film of the silicon oxide film and the silicon nitride film as the block insulating film 35, it is possible to improve a charge blocking property.

As shown in FIGS. 1 and 2, a drain side selection transistor STD is provided at the upper end portion of one of the pair of columnar sections CL in the U-shaped memory string MS. A source side selection transistor STS is provided at the upper end portion of the other.

The memory cells, the drain side selection transistor STD, and the source side selection transistor STS are vertical transistors in which an electric current flows in the stacking direction of the stacked body stacked on the substrate 10 (the Z-direction).

The drain side selection gate SGD functions as a gate electrode (a control gate) of the drain side selection transistor STD. An insulating film 51 (FIG. 2) functioning as a gate insulating film of the drain side selection transistor STD is provided between the drain side selection gate SGD and the channel body 20. The channel body 20 of the drain side selection transistor STD is connected to the bit lines BL above the drain side selection gate SGD.

The source side selection gate SGS functions as a gate electrode (a control gate) of the source side selection transistor STS. An insulating film 52 (FIG. 2) functioning as a gate insulating film of the source side selection transistor STS is provided between the source side selection gate SGS and the channel body 20. The channel body 20 of the source side selection transistor STS is connected to the source line SL above the source side selection gate SGS.

A back gate transistor BGT is provided in the joining section JP of the memory string MS. The back gate BG functions as a gate electrode (a control gate) of the back gate transistor BGT. The memory film 30 provided in the back gate BG functions as a gate insulating film of the back gate transistor BGT.

A plurality of memory cells including the respective electrode layers WL as control gates are provided between the drain side selection transistor STD and the back gate transistor BGT. Similarly, a plurality of memory cells including the respective electrode layers WL as control gates are also provided between the back gate transistor BGT and the source side selection transistor STS.

The plurality of memory cells, the drain side selection transistor STD, the back gate transistor BGT, and the source side selection transistor STS are connected in series through the channel body 20 to configure U-shaped one memory string MS. A plurality of the memory strings MS are arrayed in the X-direction and the Y-direction, whereby the plurality of memory cells are three-dimensionally provided in the X-direction, the Y-direction, and the Z-direction.

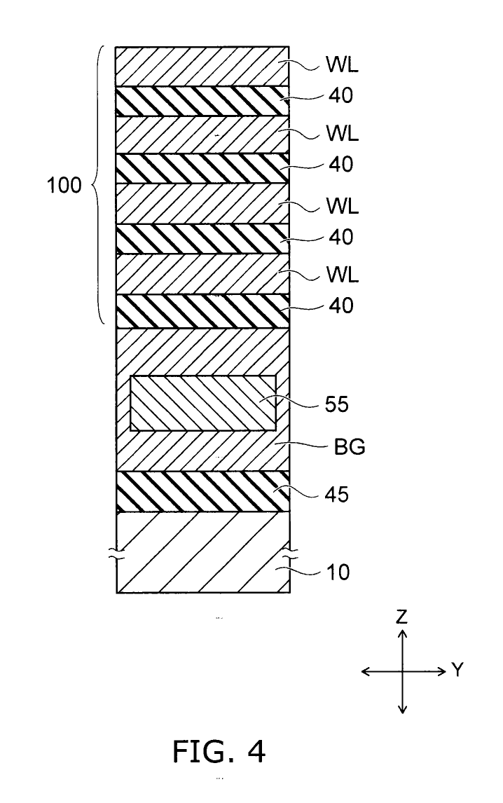

A manufacturing method for the semiconductor memory device of the embodiment is described with reference to FIGS. 4 to 13.

As shown in FIG. 4, the back gate BG is formed on the substrate 10 via the insulating layer 45. A recessed section is formed in the back gate BG. A sacrificial film 55 is filled in the recessed section. The sacrificial film 55 is, for example, a silicon nitride film. A portion where the sacrificial film 55 (the recessed section) is formed changes to a joining section JP of the memory string MS.

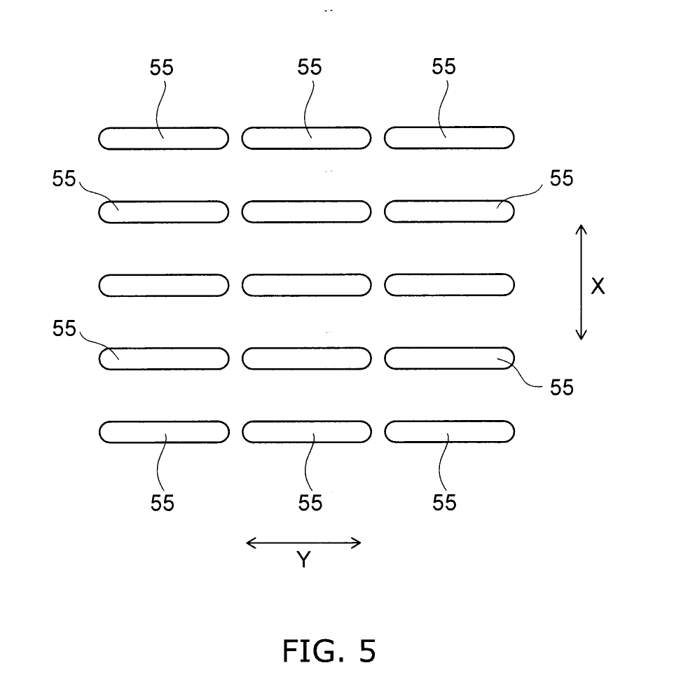

FIG. 5 is a schematic plan view of a plurality of the sacrificial films 55 (the recessed sections). The plurality of sacrificial films 55 (recessed sections) are formed to be arrayed in the Y-direction and the X-direction.

On the back gate BG, the plurality of insulating layers 40 and the plurality of electrode layers WL are alternately stacked. The insulating layers 40 and the electrode layers WL are formed by, for example, a CVD (Chemical Vapor Deposition) method.

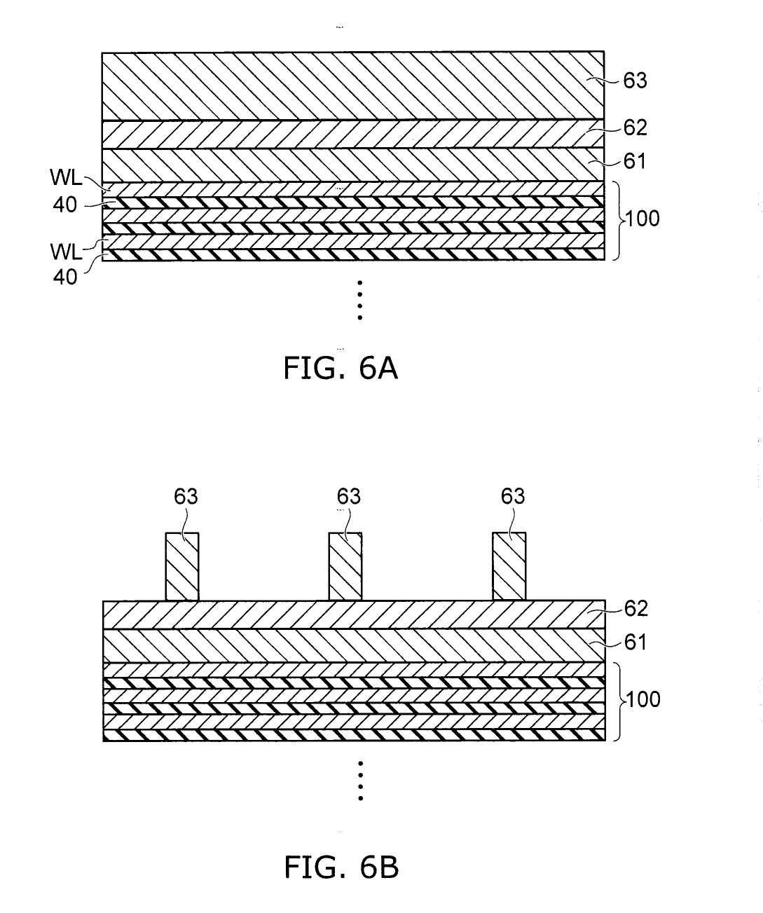

After a stacked body 100 including the electrode layers WL and the insulating layers 40 is formed, processes shown in FIG. 6A and subsequent figures are carried out. Note that the top layer of the stacked body 100 may be either the electrode layer WL or the insulating layer 40.

As shown in FIG. 6A, a base mask is formed on the stacked body 100. The base mask includes a first base mask layer 61 formed on the stacked body 100 and a second base mask layer 62 formed on the first base mask layer 61.

The first base mask layer 61 is made of a material different from the materials of the electrode layers WL and the insulating layers 40 of the stacked body 100 and is, for example, a tantalum oxide (TaO) layer. The second base mask layer 62 is made of a material different from the material of the first base mask layer 61 and is, for example, a silicon oxide (SiO₂) layer.

A core material film 63 is formed on the second base mask layer 62. The core material film 63 is made of a material different from the material of the second base mask layer 62 and is, for example, an amorphous silicon layer.

Subsequently, the core material film 63 is processed by lithography and RIE (Reactive Ion Etching). As shown in FIG. 6B, the core material film 63 is processed into a plurality of line patterns extending in a direction piercing through the paper surface.

Subsequently, first sidewall films 64 are conformally formed on the second base mask layer 62 to cover the sidewalls and the upper surfaces of the core material films 63. The first sidewall films 64 are made of a material different from the materials of the second base mask layer 62 and the core material films 63 and are, for example, silicon nitride films.

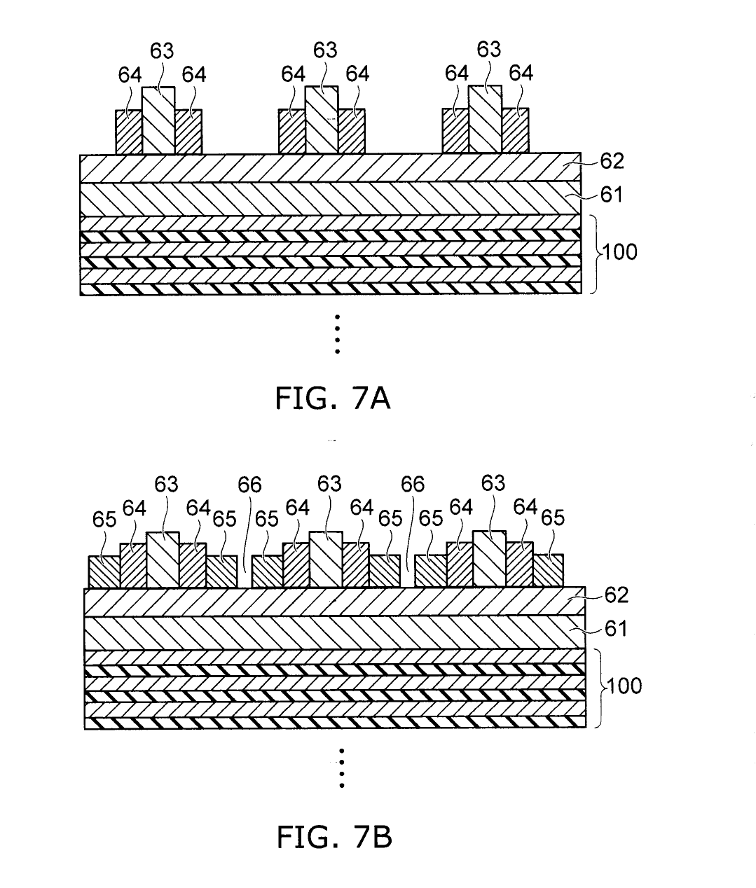

After being deposited by a film formation method (e.g., a low-pressure CVD method) excellent in a surface coating property, the silicon nitride films are etched back by the RIE. Consequently, as shown in FIG. 7A, the first sidewall films 64 are left on both the sidewalls in the width direction of the core material films 63.

Second sidewall films 65 are conformally formed on the second base mask layer 62 to cover the upper surfaces of the core material films 63 and the sidewalls and the upper surfaces of the first sidewall films 64 by the same method. The second sidewall films 65 are made of a material (e.g., amorphous silicon) same as the material of the core material films 63.

After being deposited by a film formation method (e.g., the low-pressure CVD method) excellent in the surface coating property, the amorphous silicon films are etched back by the RIE. Consequently, as shown in FIG. 7B, the second sidewall films 65 are left on both the sidewalls in the width direction of the first sidewall films 64.

The upper surfaces of the second sidewall films 65 are lower than the upper surfaces of the core material films 63 because of an etching rate difference of the etch back.

Slits 66 are formed among the second sidewall films 65 adjacent to one another among the first sidewall films 64. The slits 66 extend in the direction piercing through the paper surface.

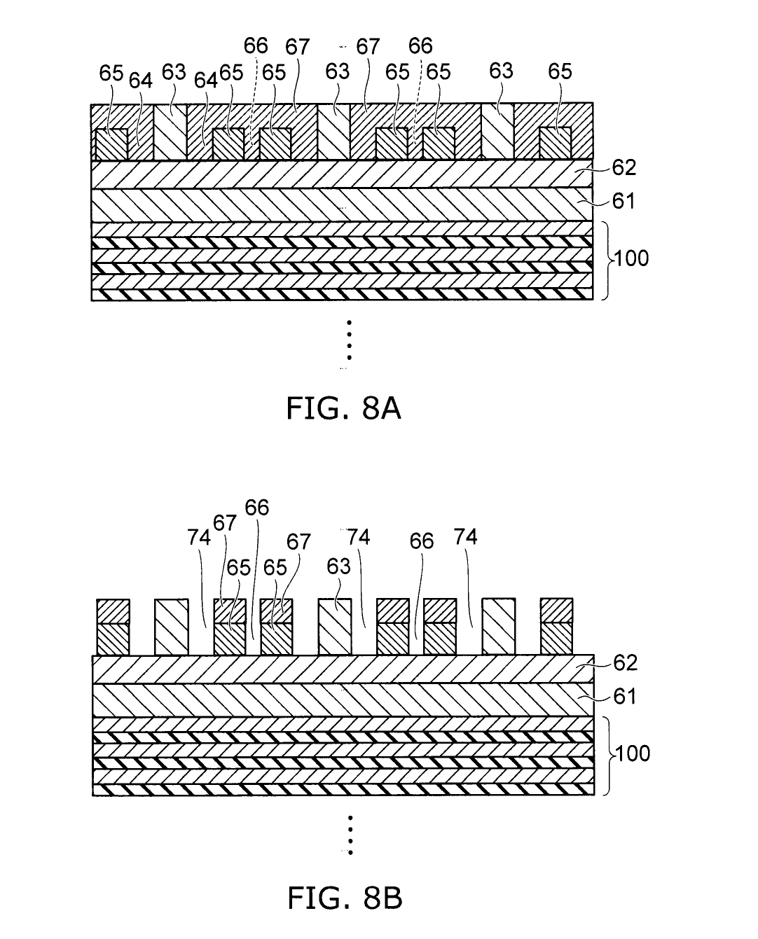

Subsequently, as shown in FIG. 8A, a mask layer 67 is formed on the second base mask layer 62 to cover the core material films 63, the first sidewall films 64, and the second sidewall films 65. The mask layer 67 is embedded in the slits 66.

The mask layer 67 is made of a material (e.g., a silicon nitride film) same as the material of the first sidewall films 64. For example, after being deposited by the low-pressure CVD method, the mask layer 67 is planarizd by a CMP (Chemical Mechanical Polishing) method.

The upper surfaces of the core material films 63 function as stoppers of the CMP. The upper surfaces of the core material films 63 are exposed from the mask layer 67. The upper surfaces of the second sidewall films 65 are covered with the mask layer 67.

Films made of the same material (e.g., silicon nitride films) are provided between the core material films 63 and the second sidewall films 65, on the upper surfaces of the second sidewall films 65, and among the second sidewall films 65 (in the slits 66).

The first sidewall films 64 and the mask layer 67 are made of the same material (e.g., silicon nitride films). Therefore, after the process of FIG. 7B, it is also possible that the first sidewall films 64 are removed and, thereafter, the mask layer 67 is formed. The mask layer 67 formed on the sidewalls of the core material films 63 is also considered to be first sidewall films.

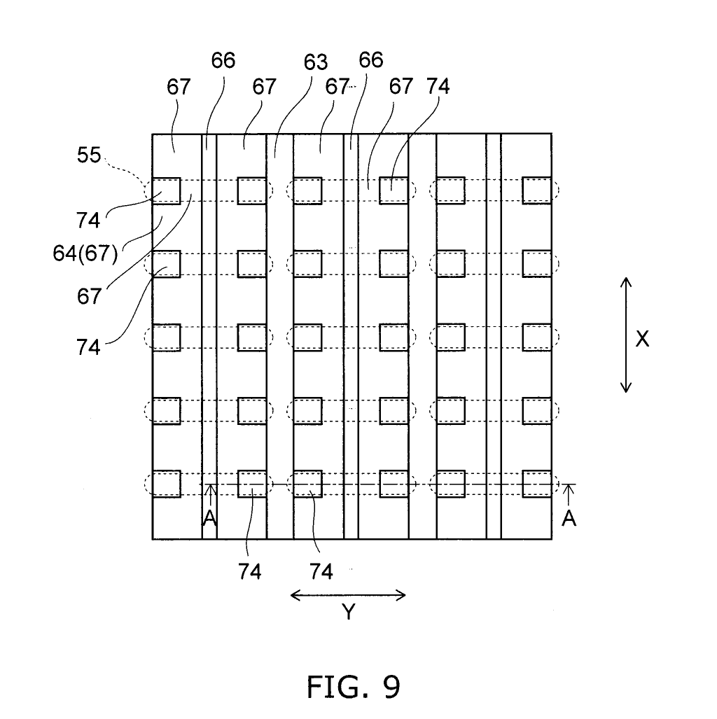

Subsequently, the first sidewall films 64 and the mask layer 67 are patterned by the lithography and the RIE. As shown in a schematic plan view of FIG. 9, the first sidewall films 64 and the mask layer 67 remaining on the first sidewall films 64 are patterned into a plurality of island shapes. In some case, the mask layer 67 does not remain on the first sidewall films 64.

FIG. 8B shows an A-A cross section in FIG. 9.

All the mask layers 67 embedded in the slits 66 among the second sidewall films 65 are entirely removed. Therefore, the second base mask layer 62 is exposed in the bottoms of the slits 66.

The mask layers 67 on the second sidewall films 65 are left. As shown in FIG. 9, the first sidewall films 64 (or the mask layers 67) formed on the sidewalls of the core material films 63 are left in regions other than the sacrificial films 55 (the recessed sections) where the joining sections JP of the memory strings MS are formed. The first sidewall films 64 (or the mask layers 67) in regions on the sacrificial films 55 (the recessed sections) are removed. Opening sections 74 are formed in the regions on the sacrificial films 55 (the recessed sections). The plane shape of the opening sections 74 is, for example, a square shape. In regions adjacent to the sidewalls of the core material films 63, regions covered with the first sidewall films 64 (or the mask layer 67) and the opening sections 74 are alternately formed along the X-direction.

The silicon oxide film (the second base mask layer 62) exposed in the slits 66 and the opening sections 74 is etched by the RIE method using the amorphous silicon films (the core material films 63 and the second sidewall films 65) and the silicon nitride films (the mask layers 67 and the first sidewall films 64) as masks.

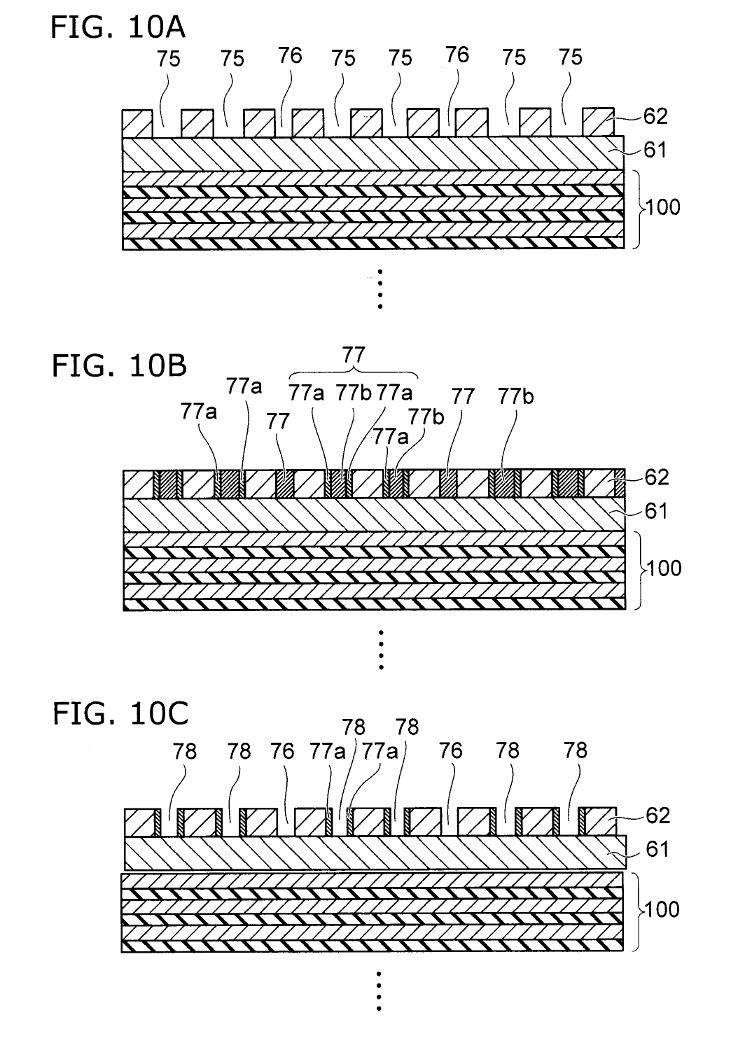

Consequently, as shown in FIG. 10A, mask holes 75 and mask slits 76 are simultaneously formed in the second base mask layer 62 by the same etching process.

The mask holes 75 are formed in a square plane shape under the opening sections 74 surrounded by the mask layers 67 and the core material films 63 in FIG. 9. The mask slits 76 are formed under the slits 66 shown in FIG. 9 and extend in the X-direction like the slits 66.

After the mask holes 75 and the mask slits 76 are formed, the core material films 63, the first sidewall films 64, the second sidewall films 65, and the mask layers 67 are removed.

Subsequently, self-organizing materials 77 are supplied into the mask holes 75 and the mask slits 76. As shown in FIG. 10B, the self-organizing materials 77 in the mask holes 75 are phase-separated into first phases 77a and second phases 77b by heat treatment.

For example, block copolymer is used as the self-organizing materials 77. The block copolymer is a high molecular compound in which two kinds of polymers chemically bind. When compatibility of the two polymers is low, the block copolymer separates (phase-separates) in a microscopic region according to repulsion between the polymers and forms a regular periodic structure according to heat treatment or the like.

In the mask holes 75, molecules of the first phases 77a are aligned in a cylindrical shape and molecules of the second phases 77b are aligned in a cylindrical shape on the inner sides of the first phases 77a. On the other hand, the width (the width in the Y-direction) of the mask slits 76 is smaller than the width (the width in the X-direction and the width in the Y-direction) of the mask holes 75. Therefore, in the mask slits 76, the self-organizing materials 77 are not phase-separated because of inconsistency of the molecular length of the self-organizing materials 77 and the slit width.

The self-organizing materials 77 are developed. As shown in FIG. 10C, the second phases 77b are selectively removed. The self-organizing materials 77 not phase-separated in the mask slits 76 are also removed by development treatment at this point. Alternatively, the self-organizing materials 77 in the mask slits 76 are separately removed using development liquid different from development liquid for removing the second phases 77b.

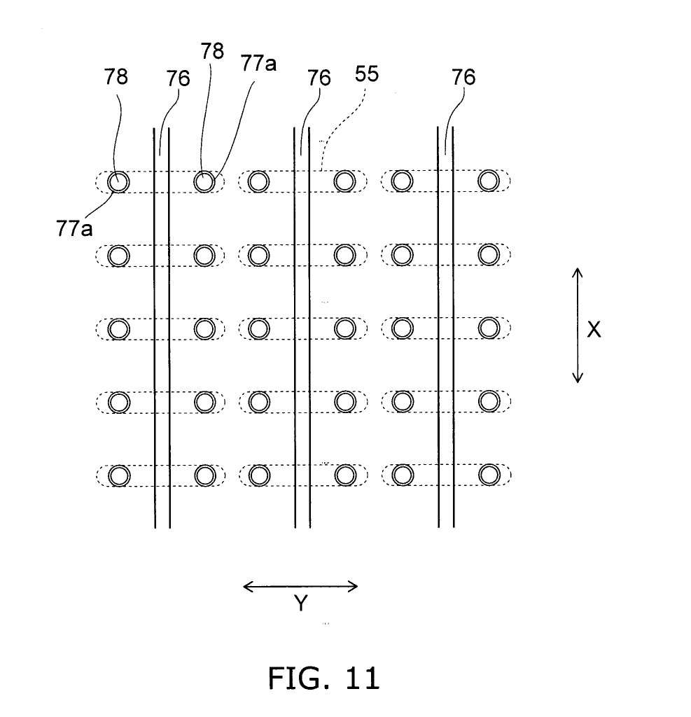

In any case, in the mask holes 75, as shown in FIG. 11, the first phases 77a are left in a cylindrical shape. Therefore, in the second base mask layer 62, circular mask holes 78 are formed in regions located on the sacrificial films 55 (the recessed sections).

The mask holes 78 and the mask slits 76 formed in the second base mask layer 62 are transcribed to the first base mask layer 61. The stacked body 100 is processed by the RIE method using the first base mask layer 61, to which the mask holes 78 and the mask slits 76 are transcribed, as masks.

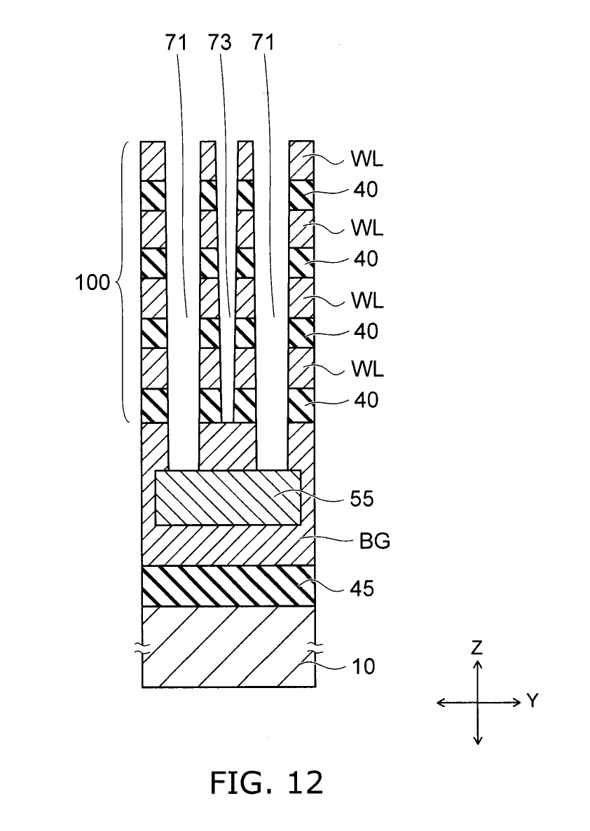

As shown in FIG. 12, a slit 73 and holes 71 are simultaneously formed in the stacked body 100. The slit 73 and the holes 71 are formed by the same etching process. The slit 73 extends in the X-direction (the direction piercing through the paper surface) and separates the stacked body 100 in the Y-direction. The lower end of the slit 73 reaches the back gate BG.

The diameter of the holes 71 is larger than the width (the width in the Y-direction) of the slit 73. The lower ends of the holes 71 reach the sacrificial film 55. The sacrificial film 55 is exposed in the bottoms of the holes 71. A pair of the holes 71 sandwiching the slit 73 in the Y-direction is located on a common sacrificial film 55.

After the holes 71 and the slit 73 are formed, the sacrificial film 55 is removed by etching through the holes 71. The sacrificial film 55 is removed by, for example, wet etching.

When the sacrificial film 55 is removed, as shown in FIG. 13, a recessed section 72 formed in the back gate BG appears. The pair of holes 71 is connected to one recessed section 72. That is, the lower ends of the pair of holes 71 are connected to one common recessed section 72 to form one U-shaped memory hole MH.

After the memory hole MH is formed, sacrificial films are formed in the memory hole MH and the slit 73. Since the width of the slit 73 is smaller than the diameter of the memory hole MH, the sacrificial film is embedded in the slit 73 but a hollow remains in the memory hole MH.

The sacrificial film in the memory hole MH is removed by wet etching. Etching liquid isotropically etches the sacrificial film in the memory hole MH through the hollow in the memory hole MH. The upper surface of the sacrificial film in the slit 73 retracts a little.

In the memory hole MH, in which the sacrificial film is removed, the memory film 30, the channel body 20, and the core insulating film 50 are formed.

Subsequently, after the sacrificial film in the slit 73 is removed and a metal film is formed on the sidewall of the slit 73, a portion on the sidewall side of the slit 73 in the electrode layer WL is metal-silicided. Thereafter, after unreacted metal in the slit 73 is removed, the isolation film 46 (FIG. 2) is embedded in the slit 73.

Thereafter, a stacked body including a selection gate is stacked on the stacked body 100 to form the selection transistors STD and STS shown in FIGS. 1 and 2. Further, the source line SL, the bit lines BL, and the like shown in FIG. 1 are formed on the insulating layer 44.

According to the embodiment described above, the memory hole MH and the slit 73 are formed in a self-aligning manner using the masks formed making use of two stages of sidewall processes. Therefore, it is possible to highly accurately secure alignment of the memory hole MH and the slit 73. For the sidewall processes, an existing lithography facility can be used. Therefore, the semiconductor memory device can be manufactured at low costs.

Further, a plurality of the memory holes MH and a plurality of the slits 73 are collectively processed. Therefore, it is possible to reduce the number of times of stacked electrode processing for a long time and reduce manufacturing costs.

The opening sections 74 shown in FIG. 9 for forming holes are formed in the square plane shape. However, a hole shape is adjusted to the circular mask holes 78 as shown in FIG. 11 making use of the phase separation of the self-organizing materials.

Therefore, the holes 71 formed in the stacked body 100 can be formed as circular holes. Since the holes 71 do not have corners, it is possible to prevent electric field concentration on the corners and provide the semiconductor memory device having high reliability.

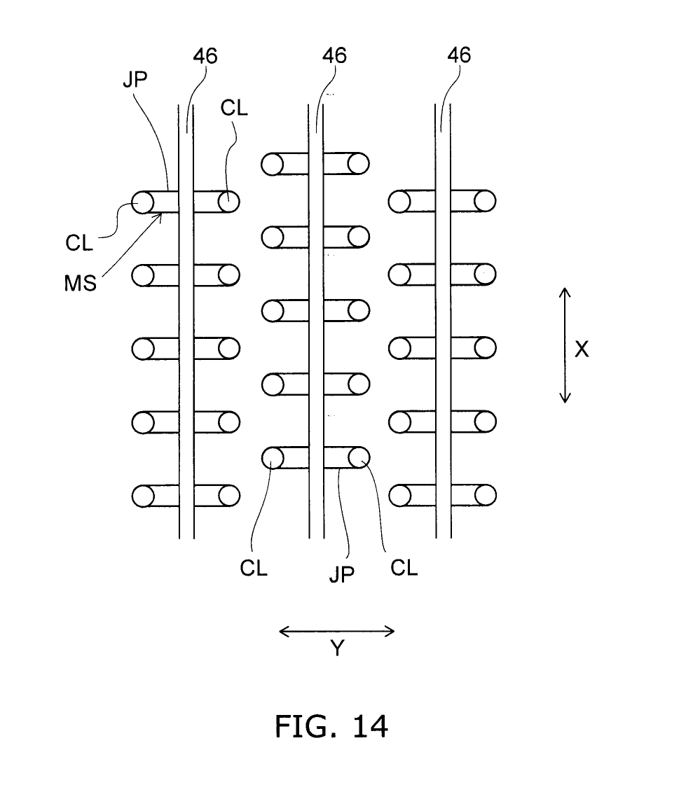

FIG. 14 is a schematic plan view showing another disposition example of the plurality of memory strings MS.

The pair of columnar sections CL sandwiching a common isolation film 46 (slit) in the Y-direction is shifted in positions in the X-direction with respect to the columnar section CL of the neighboring memory string MS in the Y-direction. The neighboring columnar section CL in the Y-direction is located in the position between the columnar sections CL adjacent to each other in the X-direction. That is, a plurality of the columnar sections CL (holes) are arrayed in zigzag.

By arraying the columnar sections CL in zigzag in this way, it is possible to reduce the distance between the columnar sections CL (the holes) adjacent to each other in the Y-direction. Therefore, it is possible to reduce costs through a reduction in a cell area and high integration of the memory cells.

Further, since the number of the memory strings MS connected to the common bit line BL extending in the Y-direction is reduced, it is also possible to improve data throughput.

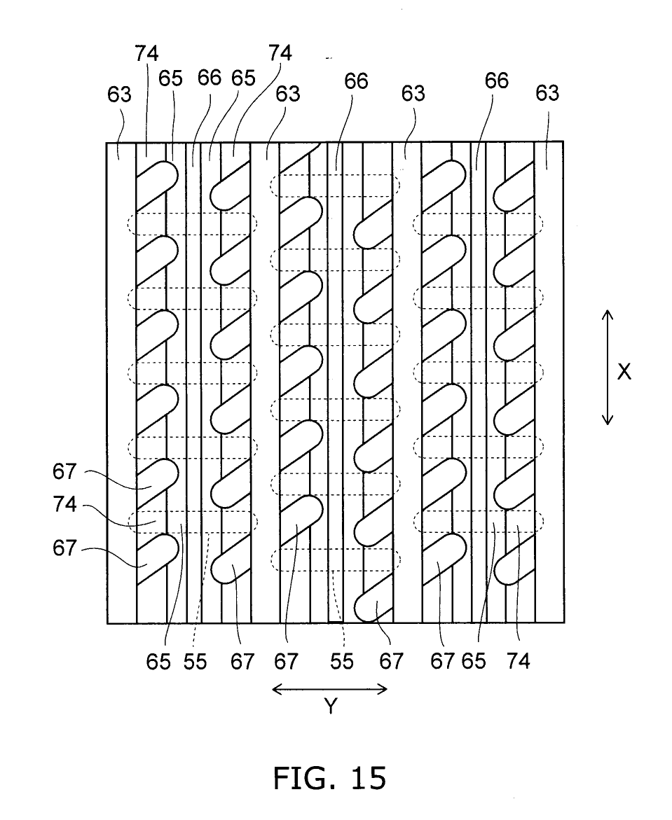

Holes for forming the columnar sections CL arrayed in zigzag in this way can be formed by, in the patterning of the silicon nitride films (the mask layers 67 and the first sidewall films 64) by the lithography and the RIE after the process shown in FIG. 8A, patterning the silicon nitride films in island shapes extending in a direction oblique to the X-direction and the Y-direction as shown in FIG. 15.

In regions adjacent to the sidewalls of the core material films 63, opening sections 74 rhombic in a plane shape are formed among the silicon nitride films (the mask layers 67 and the first sidewall films 64) adjacent to one another in the X-direction. The sacrificial films 55 (the recessed sections) are located under the opening sections 74.

The silicon oxide film (the second base mask layer 62) exposed in the slits 66 and the opening sections 74 is etched by the RIE method using the amorphous silicon films (the core material films 63 and the second sidewall films 65) and the silicon nitride films (the mask layers 67 and the first sidewall films 64) as masks.

Consequently, as in FIG. 10A referred to above, the mask holes 75 and the mask slits 76 are simultaneously formed in the second base mask layer 62.

Further, the self-organizing materials 77 are supplied into the mask holes 75 and the mask slits 76. As shown in FIG. 10B, the self-organizing materials 77 in the mask holes 75 are phase-separated into the first phases 77a and the second phases 77b by heat treatment.

The self-organizing materials 77 are developed. As shown in FIG. 10C, the second phases 77b are selectively removed. The self-organizing materials 77 not phase-separated in the mask slits 76 are also removed by development treatment at this point. Alternatively, the self-organizing materials 77 in the mask slits 76 are separately removed using development liquid different from development liquid for removing the second phases 77b.

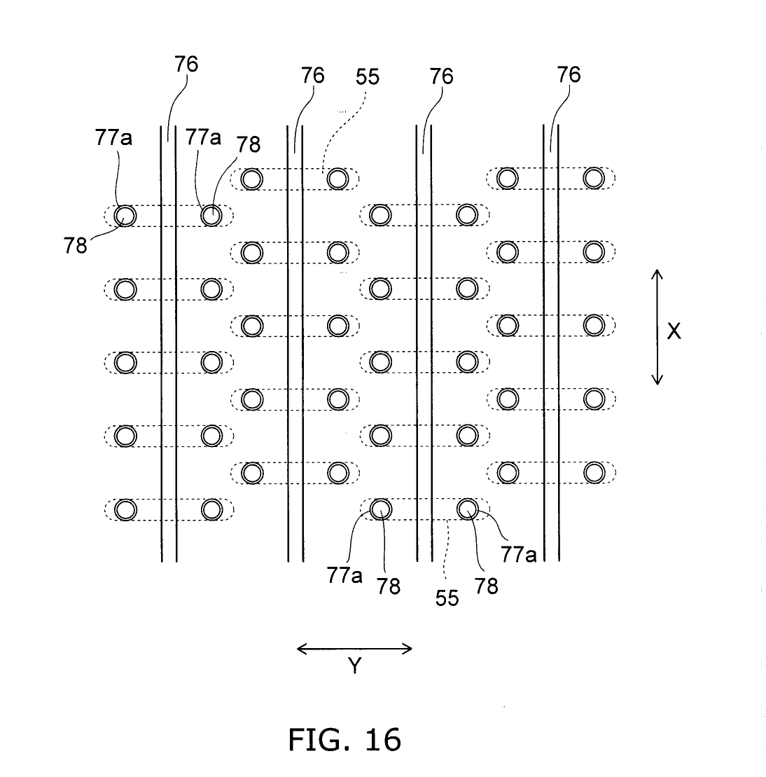

In any case, in the mask holes 75, as shown in FIG. 16, the first phases 77a are left in a cylindrical shape. Therefore, in the second base mask layer 62, the circular mask holes 78 are formed in regions located on the sacrificial films 55 (the recessed sections).

The mask holes 78 and the mask slits 76 formed in the second base mask layer 62 are transcribed to the first base mask layer 61. The stacked body 100 is processed by the RIE method using the first base mask layer 61, to which the mask holes 78 and the mask slits 76 are transcribed, as masks. As shown in FIG. 12, the slit 73 and the holes 71 are simultaneously formed in a self-aligning manner. Thereafter, the processes are carried out in the same manner as in the embodiment described above.

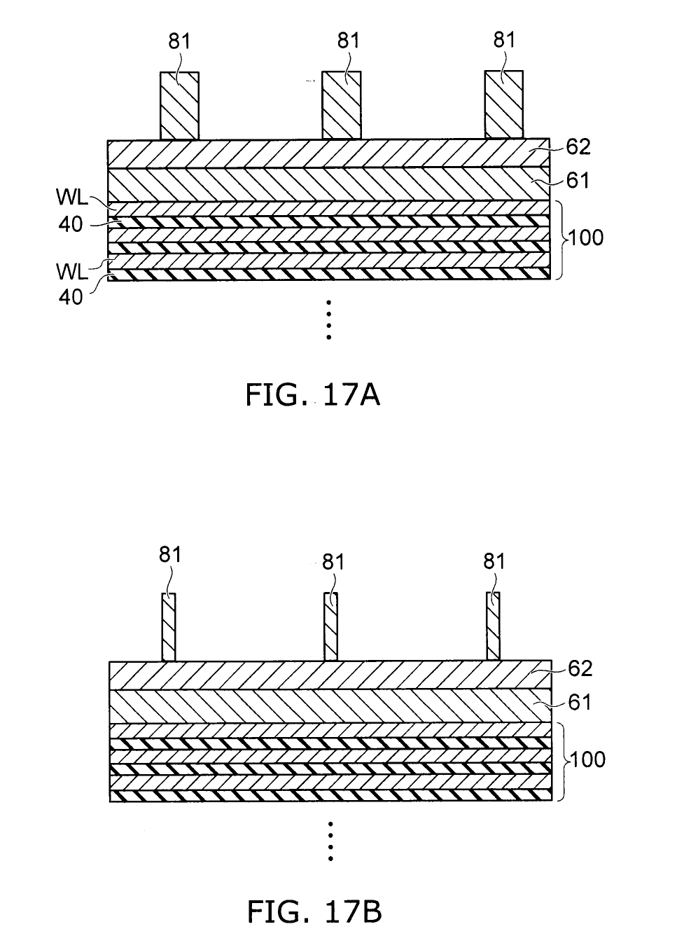

Another example of the manufacturing method for the semiconductor memory device of the embodiment is described with reference to FIGS. 17A to 21C.

As in the embodiment described above, after the stacked body 100 including the electrode layers WL and the insulating layers 40 is formed, a base mask is formed on the stacked body 100. As shown in FIG. 17A, the base mask includes the first base mask layer 61 formed on the stacked body 100 and the second base mask layer 62 formed on the first base mask layer 61.

The first base mask layer 61 is made of a material different from the materials of the electrode layers WL and the insulating layers 40 of the stacked body 100 and is, for example, a tantalum oxide (TaO) layer. The second base mask layer 62 is made of a material different from the material of the first base mask layer 61 and is, for example, a silicon oxide (SiO₂) layer.

A core material film 81 is formed on the second base mask layer 62. The core material film 81 is made of a material different from the material of the second base mask layer 62 and is, for example, a silicon nitride film.

Subsequently, the core material film 81 is processed by the lithography and the RIE. As shown in FIG. 17A, the core material film 81 is processed into a plurality of line patterns extending in the direction piercing through the paper surface.

Further, for example, isotropic wet etching is applied to the core material films 81. As shown in FIG. 17B, the width of the line-pattern core material films 81 is slimmed.

Subsequently, first sidewall films 82 are conformally formed on the second base mask layer 62 to cover the sidewalls and the upper surfaces of the slimmed core material films 81. The first sidewall films 82 are made of a material different from the materials of the second base mask layer 62 and the core material films 81 and are, for example, amorphous silicon films.

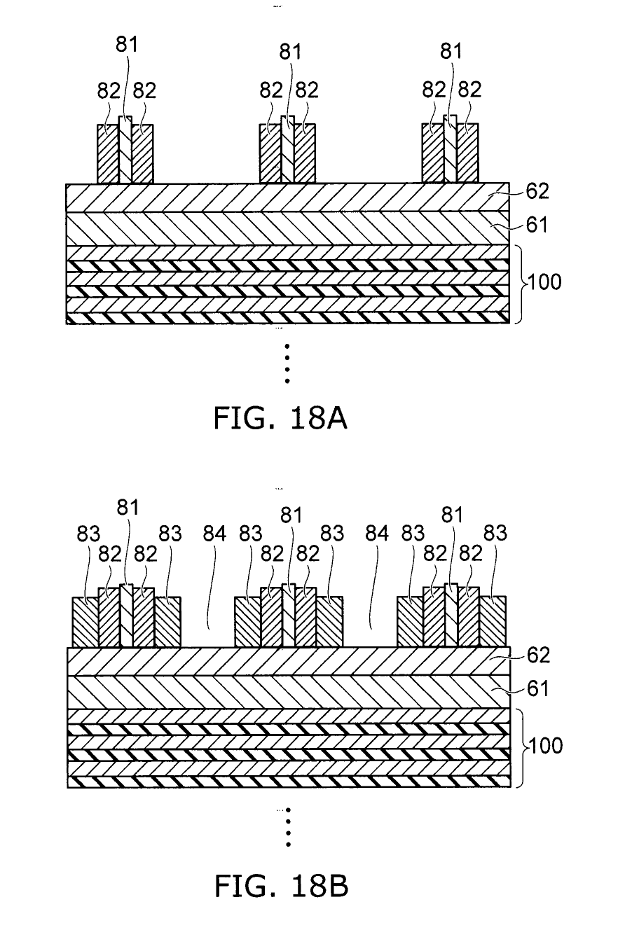

After being deposited by a film formation method (e.g., the low-pressure CVD method) excellent in a surface coating property, the amorphous silicon films are etched back by the RIE. Consequently, as shown in FIG. 18A, the first sidewall films 82 are left on both the sidewalls in the width direction of the core material films 81.

Second sidewall films 83 are conformally formed on the second base mask layer 62 to cover the upper surfaces of the core material films 81 and the sidewalls and the upper surfaces of the first sidewall films 82 by the same method. The second sidewall films 83 are made of a material (e.g., amorphous silicon) same as the material of the core material films 81.

After being deposited by a film formation method (e.g., the low-pressure CVD method) excellent in the surface coating property, the amorphous silicon films are etched back by the RIE. Consequently, as shown in FIG. 18B, the second sidewall films 83 are left on both the sidewalls in the width direction of the first sidewall films 82.

The width of the second sidewall films 83 is larger than the width of the core material films 81. Slits 84 are formed among the second sidewall films 83 adjacent to one another among the first sidewall films 82. The slits 84 extend in the direction piercing through the paper surface.

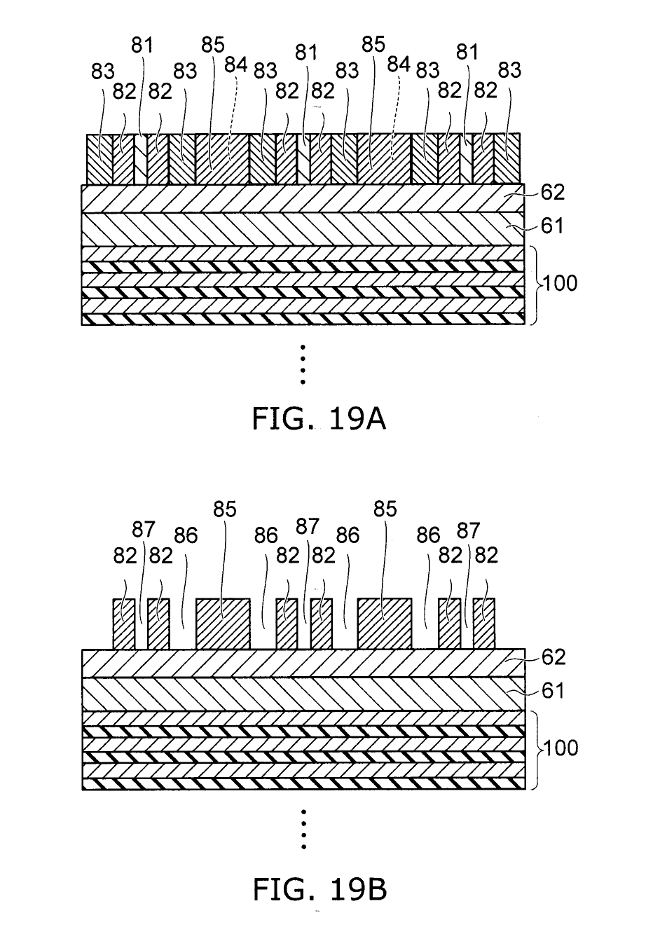

Subsequently, as shown in FIG. 19A, mask layers 85 are embedded in the slits 84. The mask layers 85 are made of a material (e.g., an amorphous silicon film) same as the material of the first sidewall films 82. For example, after being deposited by the low-pressure CVD method, the mask layers 85 are planarized by the CMP method.

Subsequently, the silicon nitride films (the core material films 81 and the second sidewall films 83) are patterned by the lithography and the RIE.

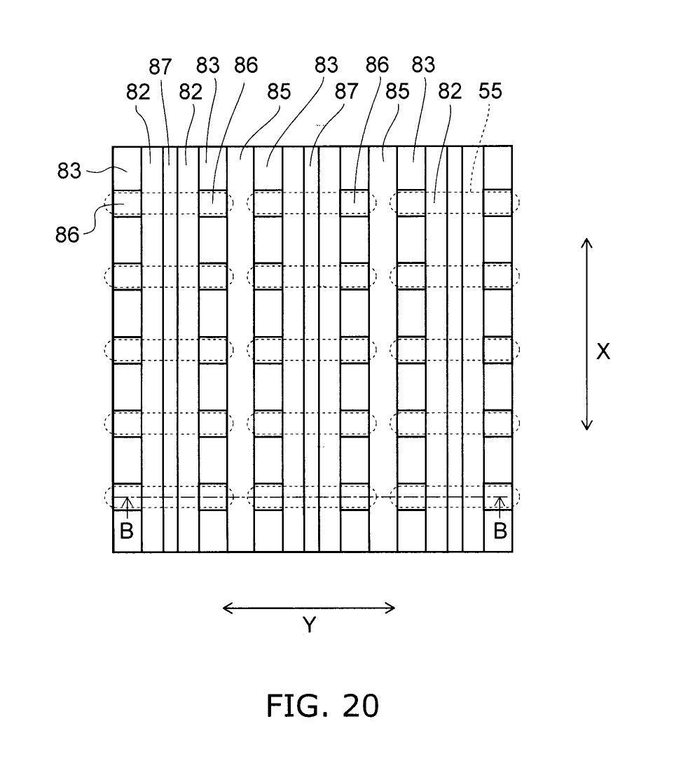

As shown in a schematic plan view of FIG. 20. The second sidewall films 83 are patterned into (left in) a plurality of island shapes.

FIG. 19B shows a B-B cross section in FIG. 20.

All the core material films 81 are removed. Slits 87 extending in the X-direction are formed. The second base mask layer 62 is exposed in the bottoms of the slits 87. Depending on the width of the slits 87, the core material films 81 do not have to be slimmed.

Opening sections 86 are formed in regions where the second sidewall films 83 are removed. The opening sections 86 are located on the sacrificial films 55 (the recessed sections). The opening sections 86 are formed in a square plane shape and surrounded by the first sidewall films 82, the second sidewall films 83, and the mask layers 85. The second sidewall films 83 and the opening sections 86 are alternately formed along the X-direction in regions adjacent to the sidewalls of the mask layers 85.

The silicon oxide film (the second base mask layer 62) exposed in the slits 87 and the opening sections 86 is etched by the RIE method using the amorphous silicon films (the first sidewall films 82 and the mask layers 85) and the silicon nitride films (the second sidewall films 83), which are left on the second base mask layer 62, as masks.

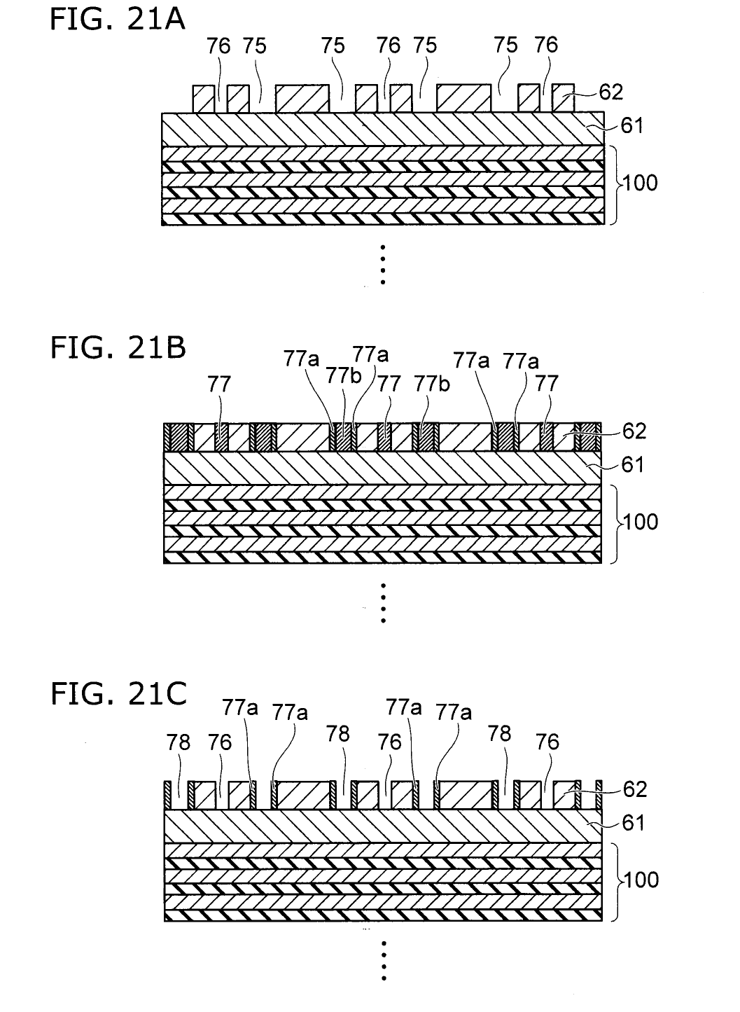

Consequently, as shown in FIG. 21A, the mask holes 75 and the mask slits 76 are simultaneously formed in the second base mask layer 62. The mask holes 75 and the mask slits 76 are formed in the same etching process.

The mask holes 75 are formed in a square plane shape under the openings 86 shown in FIG. 20. The mask slits 76 are formed under the slits 87 shown in FIG. 20 and extend in the X-direction like the slits 87.

After the mask holes 75 and the mask slits 76 are formed, the amorphous silicon films (the first sidewall films 82 and the mask layers 85) and the silicon nitride films (the second sidewall films 83) remaining on the second base mask layer 62 are removed.

Subsequently, the self-organizing materials 77 are supplied into the mask holes 75 and the mask slits 76. As shown in FIG. 21B, the self-organizing materials 77 in the mask holes 75 are phase-separated into the first phases 77a and the second phases 77b by heat treatment.

In the mask holes 75, molecules of the first phases 77a are aligned in a cylindrical shape and molecules of the second phases 77b are aligned in a columnar shape on the inner sides of the first phases 77a. On the other hand, the width (the width in the Y-direction) of the mask slits 76 is smaller than the width (the width in the X-direction and the width in the Y-direction) of the mask holes 75. Therefore, in the mask slits 76, the self-organizing materials 77 are not phase-separated because of inconsistency of the molecular length of the self-organizing materials 77 and the slit width.

The self-organizing materials 77 are developed. As shown in FIG. 21C, the second phases 77b are selectively removed. The self-organizing materials 77 not phase-separated in the mask slits 76 are also removed by development treatment at this point. Alternatively, the self-organizing materials 77 in the mask slits 76 are separately removed using development liquid different from development liquid for removing the second phases 77b.

In any case, in the mask holes 75, as shown in FIG. 11, the first phases 77a are left in a cylindrical shape. Therefore, in the second base mask layer 62, the circular mask holes 78 are formed in regions located on the sacrificial films 55 (the recessed sections).

The mask holes 78 and the mask slits 76 formed in the second base mask layer 62 are transcribed to the first base mask layer 61. The stacked body 100 is processed by the RIE method using the first base mask layer 61, to which the mask holes 78 and the mask slits 76 are transcribed, as masks. As shown in FIG. 12, the slit 73 and the holes 71 are simultaneously formed in a self-aligning manner. Thereafter, the processes are carried out in the same manner as in the embodiment described above.

In the example shown in FIGS. 17A to 21C, the memory hole MH and the slit 73 are formed in a self-aligning manner using the masks formed making use of two stages of sidewall processes. Therefore, it is possible to highly accurately secure alignment of the memory hole MH and the slit 73. For the sidewall processes, an existing lithography facility can be used. Therefore, the semiconductor memory device can be manufactured at low costs.

Further, a plurality of the memory holes MH and a plurality of the slits 73 are collectively processed. Therefore, it is possible to reduce the number of times of stacked electrode processing for a long time and reduce manufacturing costs.

The opening sections 86 shown in FIG. 20 for forming holes are formed in the square plane shape. However, a hole shape is adjusted to the circular mask holes 78 as shown in FIG. 11 making use of the phase separation of the self-organizing materials.

Therefore, the holes 71 formed in the stacked body 100 can be formed as circular holes. Since the holes 71 do not have corners, it is possible to prevent electric field concentration on the corners and provide the semiconductor memory device having high reliability.

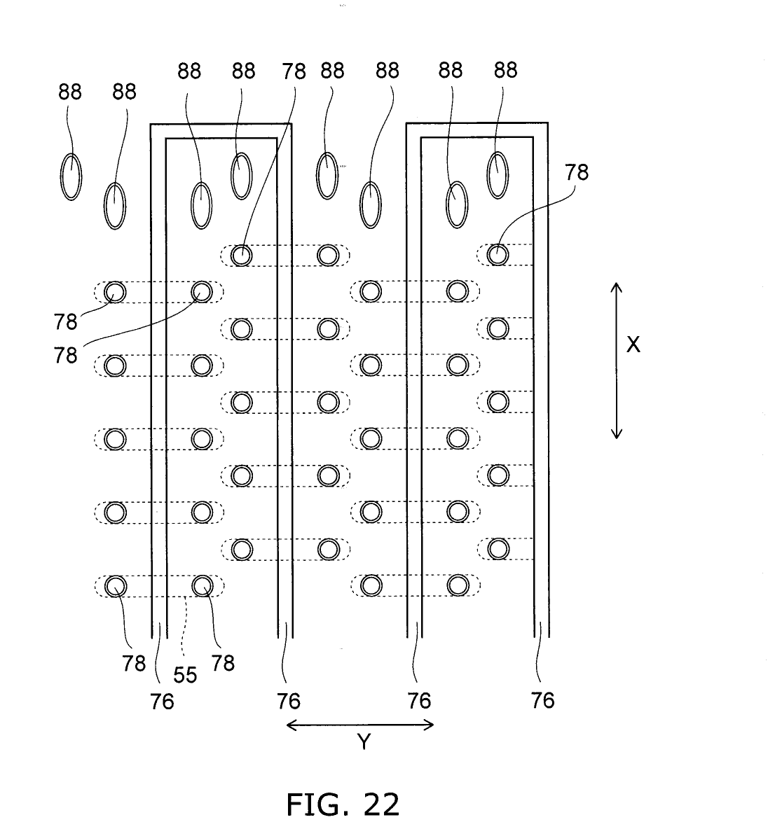

FIG. 22 is a schematic plan view of a mask pattern in an example in which, for example, the plurality of mask holes 78 are arrayed in zigzag as in FIG. 16.

FIG. 22 shows a region at the end in the X-direction of a cell array region in which the plurality of mask holes 78 are disposed. In the region at the end, end portion holes 88 having an oval shape (e.g., an elliptical shape) are formed simultaneously with the mask holes 78 and the mask slits 76.

In the region at the end, by controlling a patterning shape of the mask layers 67 left in the island shapes, it is possible to simultaneously form the mask holes 78, the mask slits 76, and the end portion holes 88 in a self-aligning manner in the second base mask layer 62.

After being formed as rectangular holes under rectangular opening sections, like the mask holes 78, the end portion holes 88 are controlled to be formed in an oval shape making use of the phase separation of the self-organizing materials.

The end portion holes 88 are not used as memory cells and function as so-called dummy patterns. In the lithography for patterning the mask layers 67 and the RIE for forming the holes, the end portion holes 88 suppress a shape change (distortion) of the holes at the end of the memory cell array region.

In an example shown in FIG. 22, the end portion holes 88 extend in a direction in which the slits 76 extend (the X-direction). By forming the end portion holes 88 in a shape extended in a direction in which the end portion holes 88 do not interfere with the slits 76, it is possible to reduce the number of dummy patterns not used as memory cells and suppress a decrease in an effective area of the cells.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A method for manufacturing a semiconductor memory device comprising:
forming a base mask on a stacked body including a plurality of electrode layers stacked via an insulating layer;
forming a plurality of core material films of line patterns on the base mask;
forming a plurality of first sidewall films on the base mask, the first sidewall films respectively provided on sidewalls of the core material films;
forming a plurality of second sidewall films on the base mask, the second sidewall films respectively provided on sidewalls of the first sidewall films, the second sidewall films adjacent to each other being separated by a slit;
processing the first sidewall films into a plurality of island shape patterns;
processing the base mask using the core material films, the first sidewall films, and the second sidewall films as masks to simultaneously form a plurality of mask slits extending in a first direction and a plurality of mask holes in the base mask;
simultaneously forming a plurality of slits extending in the first direction and a plurality of holes in the stacked body using the base mask as a mask;
forming a memory film and a channel body in the hole; and
forming an insulating film in the slit.

2. The method according to claim 1, wherein a width of the mask slit is smaller than a diameter of the mask hole.

3. The method according to claim 1, wherein the core material films and the second sidewall films are made of a same material.

4. The method according to claim 1, further comprising:
forming self-organizing materials in the mask slit and the mask hole;
phase-separating the self-organizing material in the mask hole into a first phase formed in a cylindrical shape on an inner circumferential wall of the mask hole, and a second phase formed on an inner side of the first phase; and
removing the second phase in the mask hole and the self-organizing material in the slit.

5. The method according to claim 1, wherein the mask holes are arrayed in zigzag.

6. The method according to claim 1, wherein an end portion hole having an oval shape is formed simultaneously with the mask holes and the slits in a region at an end in the first direction of a cell array region where the mask holes are disposed.

7. The method according to claim 6, wherein a major axis of the end portion hole extends in the first direction.

8. The method according to claim 1, wherein the forming the base mask includes:
forming a first base mask layer made of a material different from a material of the stacked body on the stacked body; and
forming a second base mask layer made of a material different from the material of the first base mask layer on the first base mask layer.

9. The method according to claim 1, further comprising forming, after forming the second sidewall films, a mask layer covering the second sidewall films and the slits, wherein
when the first sidewall films is processed into the island shape patterns, the mask layer in the slit is removed.

10. The method according to claim 9, wherein the first sidewall films and the mask layer are made of a same material.

11. A method for manufacturing a semiconductor memory device comprising:
forming a base mask on a stacked body including a plurality of electrode layers stacked via an insulating layer;
forming a plurality of core material films of line patterns on the base mask;
forming a plurality of first sidewall films on the base mask, the first sidewall films respectively provided on sidewalls of the core material films;
forming a plurality of second sidewall films on the base mask, the second sidewall films respectively provided on sidewalls of the first sidewall films, the second sidewall films adjacent to each other being separated by a slit;
forming a mask layer in the slit;
removing the core material films and patterning the second sidewall films into island shapes;
processing the base mask using the first sidewall films, the mask layer, and the island-shaped second sidewall films as masks to simultaneously form a plurality of mask slits extending in a first direction and a plurality of mask holes in the base mask;
simultaneously forming a plurality of slits extending in the first direction and a plurality of holes in the stacked body using the base mask as a mask;
forming a memory film and a channel body in the hole; and
forming an insulating film in the slit.

12. The method according to claim 11, further comprising slimming widths of the core material films before forming the first sidewall films.

13. The method according to claim 12, wherein the slimmed widths of the core material films are smaller than diameters of the second sidewall films.

14. The method according to claim 11, wherein the core material films and the second sidewall films are made of a same material.

15. The method according to claim 11, wherein the first sidewall films and the mask layer are made of a same material.

16. The method according to claim 11, further comprising:
forming self-organizing materials in the mask slit and the mask hole;
phase-separating the self-organizing material in the mask hole into a first phase formed in a cylindrical shape on an inner circumferential wall of the mask hole, and a second phase formed on an inner side of the first phase; and
removing the second phase in the mask hole and the self-organizing material in the slit.

17. The method according to claim 11, wherein the mask holes are arrayed in zigzag.

18. The method according to claim 11, wherein an end portion hole having an oval shape is formed simultaneously with the mask holes and the slits in a region at an end in the first direction of a cell array region where the mask holes are disposed.

19. The method according to claim 18, wherein a major axis of the end portion hole extends in the first direction.

20. The method according to claim 11, wherein the forming the base mask includes:
forming a first base mask layer made of a material different from a material of the stacked body on the stacked body; and
forming a second base mask layer made of a material different from the material of the first base mask layer on the first base mask layer.
